(19) United States
(12) Patent Application Publication
(10) Pub. No.: US 2025/0130039 A1
(43) Pub. Date: Apr. 24, 2025

(54) QUANTITATIVE ANALYSIS METHOD AND SYSTEM ON INFLUENCE OF BLACK CARBON EMISSION TO GLACIER CHANGE

(71) Applicants: Wentao Du, Lanzhou City (CN); Jizu Chen, Lanzhou City (CN); Shichang Kang, Lanzhou City (CN); Weijun Sun, Lanzhou City (CN); Youyan Jiang, Lanzhou City (CN); Xiang Qin, Lanzhou City (CN)

(72) Inventors: Wentao Du, Lanzhou City (CN); Jizu Chen, Lanzhou City (CN); Shichang Kang, Lanzhou City (CN); Weijun Sun, Lanzhou City (CN); Youyan Jiang, Lanzhou City (CN); Xiang Qin, Lanzhou City (CN)

(73) Assignee: Northwest Institute of Eco-Environment and Resources, Chinese Academy of Sciences, Lanzhou City (CN)

(21) Appl. No.: 19/001,606

(22) Filed: Dec. 26, 2024

(30) Foreign Application Priority Data
Aug. 27, 2024 (CN) 202411179167.9

(51) Int. Cl. G01B 21/20; G01N 17/00

(52) U.S. Cl. CPC G01B 21/20; G01N 17/00

(57) ABSTRACT

The present invention provides a quantitative analysis method on influence of black carbon emission to glacier change. The method includes describing a process of dry and wet snow deposition influencing albedo change by taking a specific surface area as a description parameter, calculating an specific surface area increase within a step length at the current moment according to the specific surface area at the previous moment in combination with the change of water content, and deducing to obtain a target specific surface area; establishing a light-absorbing impurity-albedo dynamic evolution model according to the target specific surface area and black carbon concentration; further coupling to an enhanced temperature index model by taking the albedo outputted by the light-absorbing impurity-albedo dynamic evolution model as a link; and calculating mass balance on a surface according to an enhanced temperature index model, and taking the mass balance as an input of a glacier dynamic model to obtain glacier change amount. The established light-absorbing impurity-albedo dynamic evolution model is coupled with the glacier dynamic model containing the enhanced temperature index model and the dynamic process to evaluate the quantitative influence of black carbon emission in history and future on the glacier change.

### TECHNICAL FIELD

The present invention belongs to the technical field of glacier ablation analysis, and particularly relates to a quantitative analysis method on influence of black carbon emission to glacier change.

### BACKGROUND

Black carbon is mainly an amorphous carbon produced by incomplete combustion of biomass and fossil fuels (e.g., coal and petroleum), and it is an important component of atmospheric aerosols.

Black carbon aerosols fell on the surface of snow/ice through dry and wet deposition, and then reduced the surface albedo and aggravated snow/ice ablation, which is an important factor affecting glacier ablation. At present, the research on black carbon in the snow/ice is mainly to collect snow/ice samples from glaciers at different altitudes interval to obtain black carbon concentrations in air, snow/ice surface, and accumulated snow pit, and then simulate the black carbon concentration changes over the whole glacier. However, it is still an unsolved task to evaluate the quantitative influence of black carbon emission in both history and future to glacier change.

### SUMMARY

The present invention provides a quantitative analysis method on influence of black carbon emission to glacier change, aiming at solving this technical problem.

Firstly, the present invention establishes a quantitative analysis method on influence of black carbon emission to glacier change, which includes:
describing a process of dry-wet deposition in snow/ice to influence albedo change by taking a specific surface area as a descripted parameter, in which, in the dry snow deposition process, a target specific surface area of snow is expressed as a logarithmic relationship between snow temperature and snow age; in the wet snow deposition process, calculating specific surface area increase within a step length at the current moment according to the specific surface area at the previous moment in combination with the change of water content, and deducing to obtain a target specific surface area at the current moment;
establishing a light-absorbing impurities-albedo dynamic evolution model according to the target specific surface area at different times and black carbon concentration;
coupling to an enhanced temperature index model by taking the albedo outputted by the light-absorbing impurity-albedo dynamic evolution model as a link, in which an expression of the coupled enhanced temperature index model is:

$${M}_{snow / ice} = \{ \begin{matrix}{TF}_{snow / ice} {T}_{air} + SRF ( 1 - α ) G {T}_{air} > {T}_{T} \\ 0 {T}_{air} \leq {T}_{T}\end{matrix} ,$$

in the expression, M_{snow/ice} refers to a snow/ice ablation amount (mm); TF_{snow/ice} refers to a snow/ice degree day factor (mm ° C.⁻¹ day⁻¹); Tₐᵢᵣ refers to an ice surface temperature (° C.); T_{T} refers to a temperature threshold for snow/ice ablation (° C.); G refers to daily mean solar radiation over whole glacier (W m⁻²); SRF refers to a radiation ablation factor (mm m² W⁻¹ day⁻¹) of snow/ice ablation; and α refers to the albedo of the glacier surface; and calculating surface mass balance according to an enhanced temperature index model, taking the mass balance as an input of a glacier dynamic model, and outputting through the glacier dynamic model to obtain the glacier change amount.

Second, the present invention provides a quantitative analysis method on influence of black carbon emission to glacier changes which includes
a description module configured to describe a process of dry and wet deposition in snow/ice influencing albedo change by taking a specific surface area as a descripted parameter, in which, in the dry snow deposition process, a target specific surface area of snow is expressed as a logarithmic relationship between snow temperature and snow age, and in the wet snow deposition process, calculate specific surface area increase within a step length at the current moment according to the specific surface area at the previous moment in combination with the change of water content, and deduce to obtain a target specific surface area at the current moment;
a construction module configured to construct a light-absorbing impurity-albedo dynamic evolution model according to the target specific surface area at different times and black carbon concentration;
a coupling module configured to couple to an enhanced temperature index model by taking the albedo outputted by the light-absorbing impurities-albedo dynamic evolution model as a link, and an expression of the coupled enhanced temperature index model is:

$${M}_{snow / ice} = \{ \begin{matrix}{TF}_{snow / ice} {T}_{air} + SRF ( 1 - α ) G {T}_{air} > {T}_{T} \\ 0 {T}_{air} \leq {T}_{T}\end{matrix} ,$$

in the expression, M_{snow/ice} refers to a snow/ice ablation amount (mm); TF_{snow/ice} refers to a snow/ice degree day factor (mm ° C.⁻¹ day⁻¹); Tₐᵢᵣ refers to an ice surface temperature (° C.); T_{T} refers to a temperature threshold for snow/ice ablation (° C.); G refers to daily mean solar radiation over whole glacier (W m⁻²); SRF refers to a radiation ablation factor (mm m² W⁻¹ day⁻¹) of snow/ice ablation; and α refers to the albedo of the glacier surface; and an output module configured to calculate surface mass balance according to an enhanced temperature index model, take the mass balance as an input of a glacier dynamic model, and output through the glacier glacier dynamic model to obtain the glacier change amount.

According to the quantitative analysis method and system on influence of black carbon emission to glacier change, the established light-absorbing impurity-albedo dynamic evolution model is coupled to the glacier dynamic model containing the enhanced temperature index model and the dynamic process to evaluate the quantitative influence of black carbon emission in history and future to the glacier change.

### BRIEF DESCRIPTION OF THE DRAWINGS

In order to more clearly illustrate the technical solution of the embodiments of the present invention, the accompanying drawings that need to be used in the description of the embodiments will be briefly introduced below, and it is obvious that the accompanying drawings in the following description are some embodiments of the present invention, and for those of ordinary skill in the art, other accompanying drawings can also be obtained according to these accompanying drawings without paying creative labor.

FIG. 1 is a flowchart of a quantitative analysis method on influence of black carbon emission to glacier change provided by an embodiment of the present invention;

FIG. 2 is a flowchart of an evaluation method for influence of black carbon emission to glacier change in a specific embodiment provided by an embodiment of the present invention; and

FIG. 3 is a structural block diagram of a quantitative analysis method on influence of black carbon emission to glacier change provided by an embodiment of the present invention.

### DETAILED DESCRIPTION OF THE PRESENT INVENTION

In order to make the objective, technical solution and advantages of the embodiments of the present invention more clear, the technical solutions in the embodiments of the present invention will be clearly and completely described below in conjunction with the accompanying drawings in the embodiments of the present invention. Definitely, the described embodiments are part embodiments of the present invention, not all embodiments. Based on the embodiments in the present invention, all other embodiments obtained by those of ordinary skill in the art without making creative labor belong to the scope of protection of the present invention.

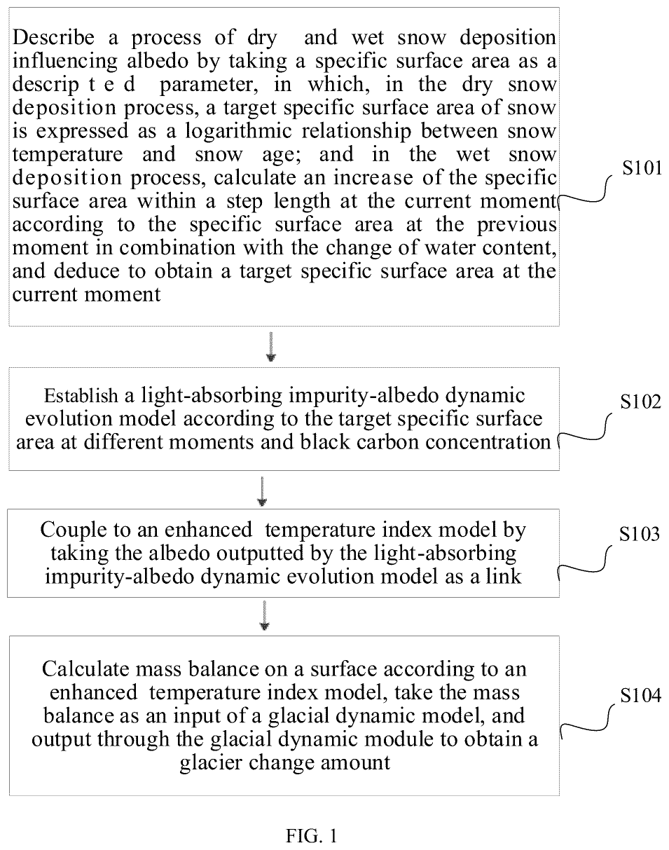

With reference to FIG. 1, it shows a flowchart of a quantitative analysis method on influence of black carbon emission to glacier change according to the present application.

As shown in FIG. 1, the quantitative analysis method on influence of black carbon emission to glacier change specifically includes the following steps:
S101: describing a process of dry wet snow deposition in snow/ice influencing albedo change by taking a specific surface area as a descripted parameter, in which, in the dry snow deposition process, a target specific surface area of snow is expressed as a logarithmic relationship between snow temperature and snow age; in the wet snow deposition process, calculating an specific surface area increase within a step length at the current moment according to the specific surface area at the previous moment in combination with the change of water content, and deducing to obtain a target specific surface area at the current moment.

In the dry snow deposition process, an expression for calculating the specific surface area is:

$$SSA ( t ) = [ 0.629 \cdot {SSA}_{initial} - 15. \cdot ( {T}_{snow} - 11.2 ) ] - [ 0.076 \cdot {SSA}_{initial} - 1.76 \cdot ( {T}_{snow} - 2.96 ) ] \cdot ln \text{} \{ t + {e}^{\frac{- 0.371 \cdot {SSA}_{initial} - 15. \cdot ( {T}_{snow} - 11.2 )}{0.076 \cdot {SSA}_{initial} - 1.76 \cdot ( {T}_{snow} - 2.96 )}} \} , \qquad ( 1 )$$

in the expression, SSAᵢₙᵢₜᵢₐₗ refers to an initial specific surface area of fresh snow, T_{snow} refers to snow temperature, and t refers to the number of days after snowfall.

In the wet snow deposition process, an expression for calculating an optical radius of snow at the current moment is:

$${R}_{opt} = \frac{3}{ρ ice \cdot SSA} , \qquad ( 2 )$$

in the expression, Rₒₚₜ refers to the optical radius of the snow at previous moment, ρice refers to ice density, and SSA refers to the specific surface area at previous moment, and the initial specific surface area is known.

In the wet snow deposition process, an expression for calculating the increment of the optical radius of snow at the different moments is:

$$Δ {R}_{opt} = \frac{{C}_{1} + {C}_{2} \cdot {θ}^{3}}{{R}_{opt}^{2} \cdot 4 π} , \qquad ( 3 )$$

in the expression, Rₒₚₜ refers to the optical radius of the snow at previous moment, and the initial optical radius of the snow is known; ΔRₒₚₜ refers to the increase of the optical radius, C₁ and C₂ refer to an empirical coefficient, and θ refers to a liquid water content expressed in percent by mass.

When glacier starts to melt, a dry snow condition is transformed into a wet snow condition. An initial specific surface area is known at the initial stage of simulation, the optical radius of snow can be obtained through the expression for calculating the optical radius of the snow at the current moment, and a new target specific surface area can be obtained by iterative computation through the expression for calculating the increase of the optical radius of the snow at different moments.

An expression for calculating the specific surface area at different moments is:

$$SSA = \frac{3}{ρ ice \cdot ( {R}_{opt} + Δ {R}_{opt} )} \qquad ( 4 )$$

S102: establishing a light-absorbing impurity-albedo dynamic evolution model according to the target specific surface area at different moments and the black carbon concentration.

The light-absorbing impurity-albedo dynamic evolution model is established according to the target specific surface area at different moments and the black carbon concentration, the quantitative analysis method on influence of black carbon emission to glacier change further includes in response to a snowfall greater than 2 cm, setting fresh snow of 2 cm on the top layer as a top snow layer, setting the residual fresh snow as a middle snow layer, and setting a previous snow layer as a bottom snow layer; in response to a snowfall less than 2 cm, directly adding the thickness of the original snow layer as well as the thickness of the fresh snow, which is regarded as uniformly mixing the snow layers with the fresh snow; uniformly mixing according to the thickness, the black carbon concentration and the water content of each snow layer; and recalculating the light-absorbing impurity concentration and the water content of all the snow layers.

When accumulated snow is melted, the middle snow layer is firstly consumed; if the middle snow layer completely disappears, the bottom snow layer is started to consume, the black carbon contained in the middle snow layer is uniformly mixed with the bottom snow layer, and when the depth of the whole snow layer is less than 2 cm, impurities in the snow layer are gradually mixed with impurities on the surface of glacier ice. The water content is calculated according to the ablation amount and the thickness of the snow layer; if the water content reaches the maximum value, any residual water seeps to the next layer below, impurities contained in the melted and evaporated or sublimated snow are enriched in the surface snow/ice, a part of impurities contained in the melted water is removed along with the melted water, and residual impurities is enriched in the surface snow/ice. Specifically, larger particular black carbon (>5 μm) is generally retained in the snow, and about 10%-30% of smaller particular black carbon impurities (˜0.2 μm) are removed along with the melted water.

According to observation of glacier ablation observation, runoff, and black carbon concentration in river, a black carbon removal coefficient in bare ice melting is calculated and calibrated based on the observed mass balance, and a black carbon enrichment process on the surface of the bare ice is calculated and iteratively simulated based on the calibrated black carbon removal coefficient, so as to obtain the black carbon concentration.

It is to be noted that the influence of the black carbon on the albedo is evaluated by adopting an albedo model containing light-absorbing impurities. The light-absorbing impurity-albedo dynamic evolution model is a snow/ice albedo parameterization scheme with a physical mechanism, and is approximately composed of the snow/ice albedo and albedo change caused by the light-absorbing impurities and the solar altitude:

$$α = {α}_{SSA} + d {α}_{c} + d {α}_{θ z} , \qquad ( 5 )$$

in the expression, α refers to the albedo of the glacier surface, α_{SSA} refers to a snow/ice albedo, dα_{c} refers to a change on the albedo caused by black carbon, and dα_{θz} refers to functions of solar altitudes _{θz} and α_{SSA}:
the value of α_{SSA} is calculated according to the specific surface area:

$${α}_{SSA} = 1.48 - {SSA}^{- 0.07} , \qquad ( 6 )$$

in the light-absorbing impurities-albedo dynamic evolution model, the black carbon is assumed to be externally mixed in snow particles, and the change on the albedo is expressed as:

$$d {α}_{C} = max ( 0.04 - {α}_{SSA} , \frac{- {C}^{0.55}}{0.16 + 0.6 {SSA}^{0.5} + 1.8 {C}^{0.6} {SSA}^{- 0.25}} ) , \qquad ( 7 )$$

dα_{θz} refers to the functions of solar altitudes _{θz} and α_{SSA}:

$$d {α}_{θ z} = 0 \text{.53} {α}_{S S A} ( 1 - ( {α}_{S S A} + d {α}_{c} ) ) {( 1 - cos θ z )}^{1.2} , \qquad ( 8 )$$

S103: coupling to an enhanced temperature index model by taking the albedo outputted by the light-absorbing impurities-albedo dynamic evolution model as a link.

In the step, an expression of the coupled enhanced temperature index model is:

$${M}_{s n o w / i c e} = \{ \begin{matrix}\begin{matrix}{TF}_{snow / ice} {T}_{air} + SRF ( 1 - α ) G & {T}_{air} > {T}_{T}\end{matrix} \\ \begin{matrix}0 & {T}_{air} \leq {T}_{T}\end{matrix}\end{matrix} , \qquad ( 9 )$$

in the expression, M_{snow/ice} refers to a snow/ice ablation amount (mm); TF_{snow/ice} refers to a snow/ice degree day factor (mm ° C.⁻¹ day⁻¹); Tₐᵢᵣ refers to an ice surface temperature (° C.); T_{T} refers to a temperature threshold for snow/ice ablation (° C.); G refers to daily mean solar radiation over whole glacier (W m⁻²); SRF refers to a radiation ablation factor (mm m² W⁻¹ day⁻¹) of snow/ice ablation; and α refers to the albedo of the glacier surface.
S104: calculating surface mass balance according to an enhanced temperature index model, and taking the mass balance as an input of a glacier dynamic model, and outputting through the glacier dynamic module to obtain a glacier change amount. ( [symbol] [symbol] [symbol] [symbol] , [symbol] [symbol] [symbol] [symbol] )

In the step, an expression of the glacier dynamic model is:

$$\frac{\partial s}{\partial t} = ω \dot{m} - ∇ \cdot q , \qquad ( 10 )$$

in the expression, ∇·q refers to an ice flux at a cross section, \dot{m} refers to mass balance, ω refers to a cross-sectional width of a glacier, ∂s refers to a velocity at the cross section, and ∂t refers to an unit time.

In conclusion, according to the method in the present application, the established light-absorbing impurities-albedo dynamic evolution model is coupled to the glacier dynamic model containing the enhanced temperature index model and the dynamic process to evaluate the quantitative influence of black carbon emission in history and future to the glacier change.

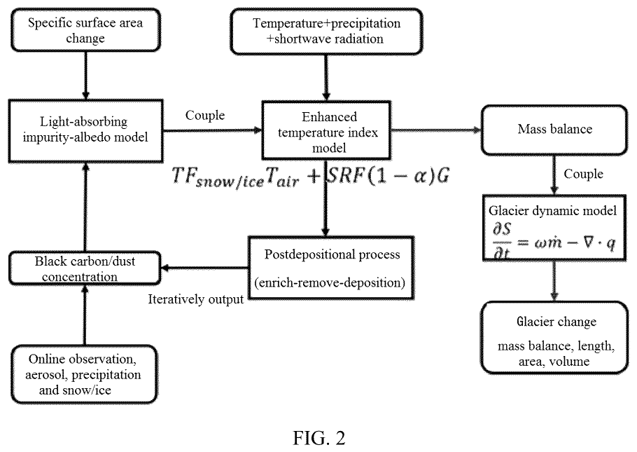

In a specific embodiment, with reference to FIG. 2, the light-absorbing impurities-albedo dynamic evolution model is established by acquiring the specific surface area change and the black carbon/dust concentration. Specifically, the black carbon/dust concentration is obtained through online observation, aerosol, precipitation and snow/ice according to post deposition process. Then, the light-absorbing impurity-albedo dynamic evolution model is coupled to obtain the enhanced temperature index model, the enhanced temperature index model calculates the surface mass balance to serve as the input of the mass balance for the glacier dynamic model, and the glacier dynamic model expresses the mass change at the glacier cross section as the sum of mass balance and ice flux change; and finally, the glacier dynamic model outputs to obtain the glacier change such as mass balance, length, area, volume and the.

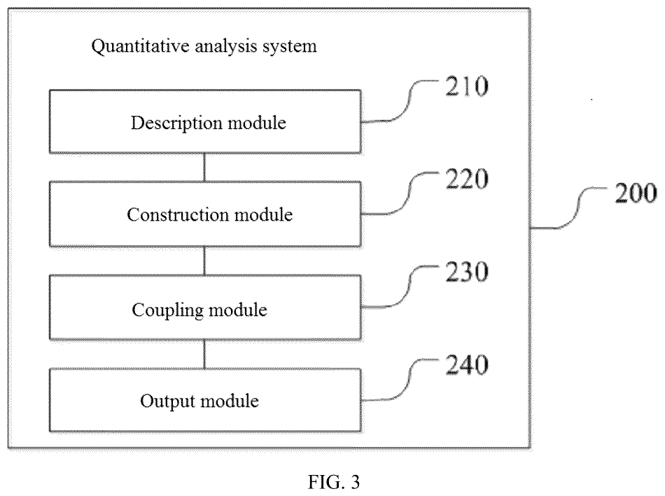

With reference to FIG. 3, it shows a structural block diagram of a quantitative analysis method on influence of black carbon emission to glacier change according to the present application.

As shown in FIG. 3, the quantitative analysis method 200 includes a description module 210, a construction module 220, a coupling module 230 and an output module 240.

The description module 210 is configured to describe a process of dry and wet deposition in snow/ice influencing albedo change by taking a specific surface area as a descripted parameter, in which, in the dry snow deposition process, a target specific surface area of snow is expressed as a logarithmic relationship between snow temperature and snow age, and in the wet snow deposition process, calculate an specific surface area increase within a step length at the current moment according to the specific surface area at the previous moment in combination with the change of water content, and deduce to obtain a target specific surface area at the current moment;
the construction module 220 is configured to construct a light-absorbing impurity-albedo dynamic evolution model according to the target specific surface area at different times and black carbon concentration;
the coupling module 230 is configured to couple to an enhanced temperature index model by taking the albedo outputted by the light-absorbing impurity-albedo dynamic evolution model as a link, and an expression of the coupled enhanced temperature index model is:

$${M}_{s n o w / i c e} = \{ \begin{matrix}\begin{matrix}{TF}_{snow / ice} {T}_{air} + SRF ( 1 - α ) G & {T}_{air} > {T}_{T}\end{matrix} \\ \begin{matrix}0 & {T}_{air} \leq {T}_{T}\end{matrix}\end{matrix} ,$$

in the expression, M_{snow/ice} refers to a snow/ice ablation amount (mm); TF_{snow/ice} refers to a snow/ice degree day factor (mm ° C.⁻¹ day⁻¹); Tₐᵢᵣ refers to an ice surface temperature (° C.); T_{T} refers to a temperature threshold for snow/ice ablation (° C.); G refers to daily mean solar radiation in a glacier area (W m⁻²); SRF refers to a radiation ablation factor (mm m² W⁻¹ day⁻¹) of snow/ice ablation; and α refers to the albedo of the glacier surface; and
the output module 240 is configured to calculate mass balance on a surface according to an enhanced temperature index model, take the mass balance as an input of a glacier dynamic model, and output through the glacier dynamic model to obtain the glacier change amount.

It is to be understood that the modules described in FIG. 3 correspond to various steps in the method described in FIG. 1. Therefore, the operations and features described above for the method and the corresponding technical effects are also applicable to the modules in FIG. 3, which will not be listed here.

Through the description of the above embodiments, those skilled in the art can clearly understand that each embodiment can be realized by means of software and necessary general hardware platform, and certainly, it can also be achieved by hardware. Based on this understanding, the essence of the above-mentioned technical solution or the part that contributes to the related art can be embodied in a form of a software product, and the computer software product can be stored in a computer-readable storage medium, such as ROM/RAM, a magnetic disk, and a CD-ROM, and includes a number of instructions to enable a computer device (which may be a personal computer, a server, or a network device, etc.) to execute each embodiment or a method of some part of the embodiment.

Finally, it is to be noted that the above embodiments are only used for illustrating the technical solution of the present invention, not to restrict it. Although the present invention is described in detail with reference to the above-mentioned embodiments, those of ordinary skill in the art should understand that they may still modify the technical solutions recorded in the above-mentioned embodiments, or perform equivalent replacement on some of the technical features therein. These modifications or replacements do not make the essence of the corresponding technical solutions detached from the spirit and scope of the technical solutions of each embodiment of the present invention.

1. A quantitative analysis method on influence of black carbon emission to glacier change, comprising:
describing a process of dry and wet deposition in snow/ice influencing albedo change by taking a specific surface area as a descripted parameter, wherein in the dry snow deposition process, a target specific surface area of snow is expressed as a logarithmic relationship between snow temperature and snow age; in the wet snow deposition process, calculating an specific surface area increase within a step length at the current moment according to the specific surface area at the previous moment in combination with the change of water content, and deducing to obtain a target specific surface area at the current moment;
establishing a light-absorbing impurity-albedo dynamic evolution model according to the target specific surface area at different moments and the black carbon concentration;
coupling to an enhanced temperature index model by taking the albedo outputted by the light-absorbing impurity-albedo dynamic evolution model as a link, wherein an expression of the coupled entrance temperature index model is:
$${M}_{s n o w / i c e} = \{ \begin{matrix}\begin{matrix}{TF}_{snow / ice} {T}_{air} + SRF ( 1 - α ) G & {T}_{air} > {T}_{T}\end{matrix} \\ \begin{matrix}0 & {T}_{air} \leq {T}_{T}\end{matrix}\end{matrix} ,$$
in the expression, M_{snow/ice} refers to a snow/ice ablation amount; TF_{snow/ice} refers to a snow/ice degree day factor; Tₐᵢᵣ refers to an ice surface temperature; T_{T} refers to a temperature threshold for snow/ice ablation; G refers to daily mean solar radiation in a glacier area; SRF refers to a radiation ablation factor of snow/ice ablation; and α refers to the albedo of the glacier surface;
an expression for calculating the albedo of the glacier surface is:
$$α = {α}_{S S A} + d {α}_{c} + d {α}_{θ z} ,$$
in the expression, α_{SSA} refers to a snow/ice albedo, dα_{c} refers to a change on the albedo caused by black carbon, and dα_{θz} refers to functions of solar altitudes _{θz} and α_{SSA};
the value of α_{SSA} is calculated according to the specific surface area SSA:
$${α}_{S S A} = 1.48 - {SSA}^{- 0.07} ,$$
in the light-absorbing impurities-albedo dynamic evolution model, the black carbon is assumed to be externally mixed in snow particles, and the change on the albedo is expressed as:
$$d {α}_{C} = max ( 0.04 - {α}_{SSA} , \frac{- {C}^{0.55}}{0.16 + 0.6 {SSA}^{0.5} + 1.8 {C}^{0.6} {SSA}^{- 0.25}} ) ,$$
dα_{θz} refers to the functions of solar altitudes _{θz} and α_{SSA}, and the expression is:
$$d {α}_{θ z} = 0 \text{.53} {α}_{S S A} ( 1 - ( {α}_{S S A} + d {α}_{c} ) ) {( 1 - cos θ z )}^{1.2} ;$$
calculating mass balance on a surface according to an enhanced temperature index model, taking the mass balance as an input of a glacier dynamic model, and outputting through the glacier dynamic module to obtain a glacier change amount, wherein an expression of the glacier dynamic model is:
$$\frac{\partial s}{\partial t} = ω \dot{m} - ∇ \cdot q ,$$
in the expression, ∇·q refers to an ice flux at a cross section, \dot{m} refers to the mass balance, ω refers to a cross-sectional width of a glacier, ∂s refers to a velocity at the cross section, and ∂t refers to an unit time.

2. The quantitative analysis method on influence of black carbon emission to glacier change according to claim 1, wherein in the wet snow deposition process, an expression for calculating an optical radius of snow at the current moment is:
$${R}_{opt} = \frac{3}{ρ ice \cdot SSA} ,$$
in the expression, Rₒₚₜ refers to the optical radius of the snow, ρice refers to ice density, and SSA refers to the specific surface area.

3. The quantitative analysis method on influence of black carbon emission to glacier change according to claim 1, wherein in the wet snow deposition process, an expression for calculating an increase of the optical radius of snow at different moments is:
$$Δ {R}_{opt} = \frac{{C}_{1} + {C}_{2} \cdot {θ}^{3}}{{R}_{opt}^{2} \cdot 4 π} ,$$
in the expression, ΔRₒₚₜ refers to the increase of the optical radius, C₁ and C₂ refer to an empirical coefficient, θ refers to a liquid water content in percent by mass, and Rₒₚₜ refers to the optical radius of snow.

4. The quantitative analysis method on influence of black carbon emission to glacier change according to claim 1, wherein in the dry snow deposition process, an expression for calculating the target specific surface area is:
$$SSA ( t ) = [ 0.6 \; 29 \cdot {SSA}_{i n i t i a l} - 15. \cdot ( {T}_{s n o w} - 11.2 ) ] - [ 0. 76 \cdot SS {A}_{i n i t i a l} - 1 \text{.76} \cdot ( {T}_{s n o w} - 2.96 ) ] \cdot ln \{ t + {e}^{\frac{- 0.371 \cdot SS {A}_{i n i t i a l} - 150 \cdot ( {T}_{s n o w} - 11.2 )}{0.0 \; 76 \cdot SS {A}_{i n i t i a l} - 1 \text{.76} \cdot ( {T}_{s n o w} - 2.96 )}} \} ,$$
in the expression, SSAᵢₙᵢₜᵢₐₗ refers to an initial specific surface area of fresh snow, T_{snow} refers to snow temperature, and t refers to the number of days after snowfall.

5. The quantitative analysis method on influence of black carbon emission to glacier change according to claim 1, wherein before establishing a light-absorbing impurity-albedo dynamic evolution model according to the target specific surface area at different moments and black carbon concentration, the method further comprises:
in response to a snowfall greater than 2 cm, setting fresh snow of 2 cm on the top layer as a top snow layer, setting the residual fresh snow as a middle snow layer, and setting a previous snow layer as a bottom snow layer; in response to a snowfall less than 2 cm, directly uniformly mixing the snow layers with the fresh snow, uniformly mixing according to the thickness, the black carbon concentration and the water content of each snow layer, and recalculating the light-absorbing impurity concentration and the water content of all the snow layers;
when accumulated snow melt, the middle snow layer is firstly consumed; if the middle snow layer completely disappears, starting to consuming the bottom snow layer, wherein the black carbon contained in the middle snow layer is uniformly mixed with the bottom snow layer, and when the depth of the whole snow layer is less than 2 cm, impurities in the snow layer are gradually mixed with impurities on the surface of glacier ice; calculating the water content according to the melting amount and the thickness of the snow layer; if the water content reaches the maximum value, any residual water seeps to the next layer below, impurities contained in the melted and evaporated or sublimated snow are enriched in the surface snow/ice, a part of impurities contained in the melted water is removed along with the melted water, and the rest of impurities is enriched in the surface snow/ice; and
according to observation of glacier ablation, runoff, and black carbon concentration in river, calculating and calibrating a black carbon removal coefficient in bare ice melting based on the observed mass balance, and calculating and iteratively simulating a black carbon enrichment process on the surface of the bare ice based on the calibrated black carbon removal coefficient, so as to obtain the black carbon concentration.

6. A quantitative analysis system on influence of black carbon emission to glacier change according to any one of claims 1 to 5, comprising:
a description module configured to describe a process of dry and wet snow deposition influencing albedo change by taking a specific surface area as a description parameter, wherein in the dry snow deposition process, a target specific surface area of snow is expressed as a logarithmic relationship between snow temperature and snow age, and in the wet snow deposition process, calculate specific surface area increase within a step length at the current moment according to the specific surface area at the previous moment in combination with the change of water content, and deduce to obtain a target specific surface area at the current moment;
a construction module configured to establish a light-absorbing impurity-albedo dynamic evolution model according to the target specific surface area at different times and black carbon concentration;
a coupling module configured to couple to an enhanced temperature index model by taking the albedo outputted by the light-absorbing impurity-albedo dynamic evolution model as a link, wherein an expression of the coupled enhanced temperature index model is:
$${M}_{s n o w / i c e} = \{ \begin{matrix}\begin{matrix}{TF}_{snow / ice} {T}_{air} + SRF ( 1 - α ) G & {T}_{air} > {T}_{T}\end{matrix} \\ \begin{matrix}0 & {T}_{air} \leq {T}_{T}\end{matrix}\end{matrix} ,$$
in the expression, M_{snow/ice} refers to a snow/ice ablation amount; TF_{snow/ice} refers to a snow/ice degree day factor; Tₐᵢᵣ refers to an ice surface temperature; T_{T} refers to a temperature threshold for snow/ice ablation; G refers to daily mean solar radiation in a glacier area; SRF refers to a radiation ablation factor of snow/ice ablation; and α refers to the albedo of the glacier surface; and
an output module configured to calculate mass balance on a surface according to an enhanced temperature index model, take the mass balance as an input of a glacier dynamic model, and output through the glacier dynamic model to obtain the glacier change amount.
